(19) United States
(12) Patent Application Publication
(10) Pub. No.: US 2008/0157234 A1
(43) Pub. Date: Jul. 3, 2008

(54) Semiconductor device and method of manufacturing the same

(76) Inventor: Ji Ho Hong, Hwaseong-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/930,293

(22) Filed: Oct. 31, 2007

(30) Foreign Application Priority Data
Dec. 27, 2006 (KR) 10-2006-0135754

(51) Int. Cl. H01L 29/78; H01L 21/336

(52) U.S. Cl. 257/413; 438/303; 257/E21.409; 257/E29.255

(57) ABSTRACT

Provided are a semiconductor device and a method of manufacturing the same. In the semiconductor device, an insulating layer and a polysilicon layer are formed on a substrate, and a notch region is formed at a portion of the polysilicon layer contacting the insulating layer. The widths of the polysilicon layer and the insulating layer are respectively reduced in the notch region.

### CROSS-REFERENCE TO RELATED APPLICATION

The present application claims the benefit under 35 U.S.C. §119 of Korean Patent Application No. 10-2006-0135754, filed Dec. 27, 2006, which is hereby incorporated by reference in its entirety.

### BACKGROUND

The performances of semiconductor devices are greatly affected by the critical dimension (CD) of a gate. That is, as the CD of a gate decreases, a signal of the gate can be transmitted well, so that a performance of a device may be performed without error. Also, as the CD of the gate decreases, the size of a device reduces, such that a higher integration can be achieved.

Accordingly, research for reducing the CD of a gate in a semiconductor device is actively under development.

The CD of a gate can be determined according to capability of a photolithography process technique and an etching process technique of polysilicon.

Accordingly, there have been new technical changes in the photolithography process technique and the etching process technique of polysilicon. For example, according to one photolithography process technique, a related art photolithography equipment using a KrF light source (248 nm wavelength) is replaced with new photolithography equipment using an ArF light source (193 nm wavelength). Furthermore, in an aspect of the etching process technique of polysilicon, research for advanced processing conditions satisfying a line edge roughness (LER) property for a profile after an etching process and the smaller CD of a gate is actively being pursued.

However, since the photolithography equipment using an ArF light source (193 nm wavelength) is very expensive, the manufacturing cost increases.

Moreover, as described above, although there are many research activities going on, there are still limitations in improving the performance of the semiconductor device.

### BRIEF SUMMARY

Accordingly embodiments of the present invention provide a semiconductor device capable of reducing a manufacturing cost and a method of manufacturing the same. Certain embodiments of the present invention can utilize related art photolithography equipment using a KrF light source.

Embodiments of the present invention also provide a semiconductor device capable of improving its performance by reducing a CD of a gate and a method of manufacturing the same.

In one embodiment, a semiconductor device includes: an insulating layer on a substrate; a polysilicon layer on the insulating layer; and a notch region on the polysilicon layer contacting the insulating layer. Respective widths of the polysilicon layer and the insulating layer are reduced in the notch region.

In another embodiment, a method of manufacturing a semiconductor device, includes: sequentially forming an insulating material, a polysilicon material, and a mask material on a substrate; performing a first dry etching process to form an insulating layer, a polysilicon layer, and a mask layer; and performing a second dry etching process using the mask layer as a mask to form a notch region on the insulating layer and a bottom region of the polysilicon layer. In a further embodiment, the method can include forming spacers on sides of the polysilicon layer having the notch region; forming source/drain regions in the substrate; and forming a silicide layer on the polysilicon layer and the source/drain regions.

The details of one or more embodiments are set forth in the accompanying drawings and the description below. Other features will be apparent from the description and drawings, and from the claims.

### BRIEF DESCRIPTION OF THE DRAWINGS

FIG. 1 is a cross-sectional view of a semiconductor device according to an embodiment of the present invention.

FIG. 2A to 2D are cross-sectional views of a manufacturing process for a semiconductor device according to an embodiment of the present invention.

### DETAILED DESCRIPTION

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

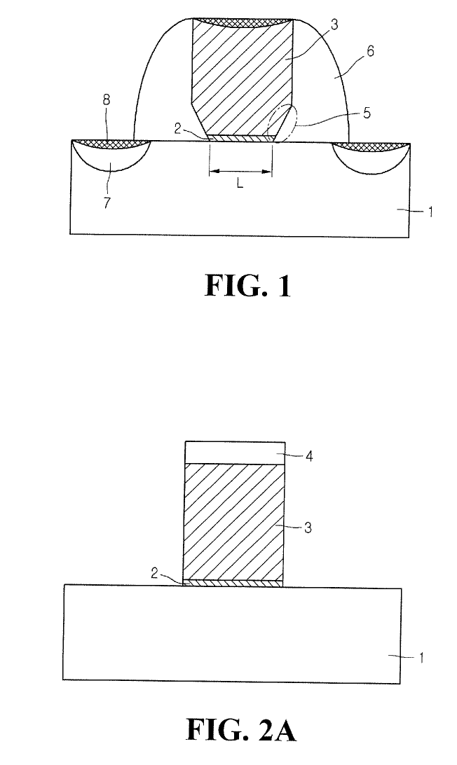

FIG. 1 is a cross-sectional view of a semiconductor device according to an embodiment.

Referring to FIG. 1, a transistor including a gate oxide layer 2 and a polysilicon layer 3 can be formed on a semiconductor substrate 1.

A notch region 5 is formed at a lower portion of the polysilicon layer 3 and the side of the gate oxide layer 2. The notch region 5 can be wider at its bottom than at its top. That is, the notch region 5 slants inward as it approaches the substrate 1. Since the notch region 5 is formed along the side of the lower portion of the polysilicon layer 3, the bottom width of the polysilicon layer 3 drastically increases. Accordingly, the critical dimension (CD) of the polysilicon layer 3 also reduces at the notch region 5.

Moreover, the polysilicon layer 3 and the gate oxide layer 2 may be formed with the same width at the lower portion of the notch region 5. Typically, the width of the gate oxide layer 2 is defined by a channel length L. Accordingly, the channel length L of the gate oxide layer 2 may be drastically reduced by the notch region 5.

The polysilicon layer 3 and the gate oxide layer 2 provide a gate of a transistor,

Since the channel length L of the gate oxide layer 2 is drastically reduced, a gate signal can be more easily transmitted such that required device functions can be performed without errors. Consequently, the performance of the device can be significantly improved.

The semiconductor device can also include a spacer 6 on sides of the polysilicon layer 3 having the notch region 5. The spacer 6 can be formed of, for example, a double layer structure of a silicon oxide SiO₂ layer and a silicon nitride Si₃N₄ layer or a three layer structure of a first silicon oxide SiO₂ layer, a silicon nitride Si₃N₄ layer, and a second silicon oxide SiO₂ layer.

The spacer 6 can function to simultaneously support the polysilicon layer 3 and inhibits the leakage of the gate signal supplied to the polysilicon layer 3.

Source/drain regions 7 can be formed in the semiconductor substrate 1.

A silicide layer 8 can also be included on the source/drain regions 7 and the polysilicon layer 3 in order to reduce a contact resistance. The silicide layer 8 may be formed of, for example, cobalt silicon CoSi₂.

Accordingly, a semiconductor device with a thin film transistor can be realized.

According to an embodiment, the performance of the semiconductor device can be improved by reducing the CD of the polysilicon layer 3 and the gate oxide layer 2, and also the channel length L of the gate.

Additionally, according to an embodiment, since the related art process equipment using the KrF light source can be used, a manufacturing cost can be reduced.

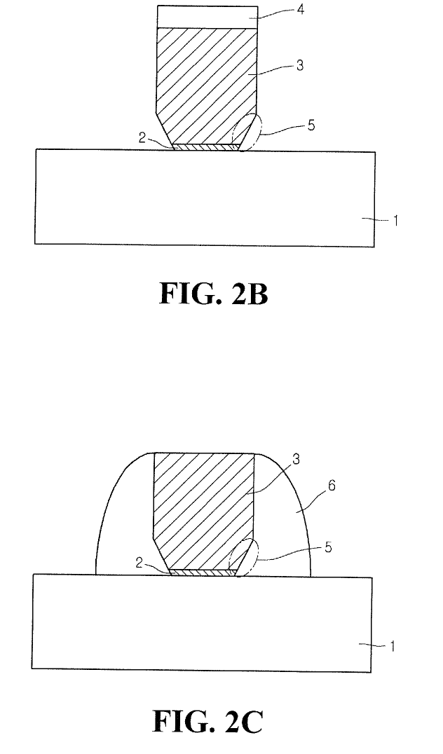

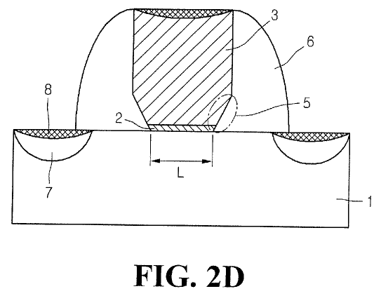

FIG. 2A to 2D are cross-sectional views of a manufacturing process for a semiconductor device according to an embodiment.

Referring to FIG. 2A, a thermal oxidation process can be performed on the surface of a semiconductor substrate 1 to form a gate oxide layer 2. Before forming the gate oxide layer 2, a device isolation layer (not shown) may be formed on the semiconductor substrate 1 to define a device region. A unit device may be defined by the device isolation layer.

A polysilicon material and a mask layer can be deposited on the gate oxide layer 2. The mask layer can be a silicon oxide SiO₂. A photoresist pattern (not shown) can be formed on the mask layer by performing a photolithography process.

A dry etching process can be performed using the photoresist pattern as a mask to, in a continuous process, etch the mask layer, the polysilicon material, and a gate oxide layer 2, such that the gate oxide layer 2, a polysilicon layer 3, and a mask pattern 4 are formed on the semiconductor substrate 1. The dry etching process can be performed by reactive ion etching (RIE). Conditions for the RIE can include a pressure ranging between 55 and 85 m Torr, a source power ranging between 550 and 900 W, a bias power ranging between 50 and 70 W, and gas including HBr, He, and O₂. The HBr flow can range between 320 and 480 scem, and the He/O₂ flow can range between 12 and 18 sccm.

An anisotropic etching process can be performed by the high source power and the He gas.

Next, the photoresist pattern is stripped and removed.

Referring to FIG. 2B, a second dry etching process can be performed using the mask pattern 4 as a mask to form a notch region 5 on the side of the lower part of the polysilicon layer 3 and the side of the oxide layer 2.

The second dry etching process can be performed by RIE. Conditions for the RIE can include a pressure ranging between 10 and 14 mTorr, a source power ranging between 140 and 210 W, a bias power ranging between 50 and 60 W, and gas including HBr and O₂. The HBr flow can range between 120 and 180 sccm, and the 02 flow can range between 3 and 5 sccm.

Since a relatively low pressure and low source power are used, but not the He for the second dry etching process, the notch region 5 can be formed on the bottom portion of the polysilicon layer 3.

The notch region 5 is formed to slant toward the center of the polysilicon layer 3. Since the notch region 5 is formed on the side of the lower part of the polysilicon layer 3, the width of the bottom of the polysilicon layer 3 may be drastically reduced, compared to the width of the top of the polysilicon layer 3. Accordingly, the CD of the polysilicon layer 3 may be also reduced at the notch region 5. Furthermore, the polysilicon layer 3 and the gate oxide layer 2 may have the same width at the lower portion of the notch region 5. Accordingly, the width of the gate oxide layer 2 may drastically decrease, compared to a related art gate oxide layer. Typically, the width of the gate oxide layer 2 can define a channel length L. Accordingly, the channel length L of the gate oxide layer 2 may be significantly reduced by the formation of the notch region 5.

The polysilicon layer 3 and the gate oxide layer 2 provide a gate of a transistor having a reduced channel length.

Since the channel length L of the gate oxide layer 2 is drastically reduced, a gate signal can be more easily transmitted such that required device functions can be performed without errors. Consequently, the performance of the device can be significantly improved.

Next, the mask layer pattern 4 can be removed.

Referring to FIG. 2C, an insulating material can be formed on the semiconductor substrate having the notch region 5. Then, an etch back process can be performed to form a spacer 6 at sides of the polysilicon layer 3.

Referring to FIG. 2D, source/drain regions 7 can be formed on the semiconductor substrate 1. The source/drain regions 7 can be formed by doping impurity materials through an ion implantation process. Due to the impurity materials, the source/drain regions 7 have a conductive property.

A metal layer can be deposited on the semiconductor substrate 1 having the source/drain regions 7 and then heat treated, such that a silicide layer 8 is formed in the source/drain regions 7 and the polysilicon layer 3 to reduce a contact resistance between lines. In one embodiment, the metal layer can include cobalt. Accordingly, a semiconductor device having a thin film transistor can be manufactured.

As described above, according to an embodiment, since the notch region is formed at a lower region of the polysilicon layer, the width of the gate oxide layer defining the channel length can be drastically reduced, such that the performance of the device can be improved.

According to an embodiment, since related art process equipment can be used, a manufacturing cost can be reduced.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifcations in the component parts and/or arrangements, alternative uses will also be apparent to those skilled in the art.

What is claimed is:

1. A semiconductor device comprising:
an insulating layer on a substrate;
a polysilicon layer on the insulating layer; and
a notch region at a portion of the polysilicon layer contacting the insulating layer,
wherein respective widths of the polysilicon layer and the insulating layer are reduced at the notch region.

2. The semiconductor device according to claim 1, wherein the notch region slants toward a center region of the polysilicon layer.

3. The semiconductor device according to claim 1, wherein the insulating layer and the polysilicon layer have a same width in the notch region.

4. The semiconductor device according to claim 1, wherein the notch region is formed on a side of a lower portion of the polysilicon layer and a side of the insulating layer.

5. The semiconductor device according to claim 1, wherein a channel length of the insulating layer is reduced by the notch region.

6. The semiconductor device according to claim 1, wherein the insulating layer and the polysilicon layer provide a gate of a transistor, and a critical dimension of the gate is reduced by the notch region.

7. The semiconductor device according to claim 6, wherein a channel length of the transistor is reduced by the notch region.

8. The semiconductor device according to claim 1, further comprising:
spacers at sides of the polysilicon layer;
source/drain regions on the substrate; and
a silicide layer on the polysilicon layer and the source/drain regions.

9. A method of manufacturing a semiconductor device, comprising:
forming an insulating material, a polysilicon material, and a mask material on a substrate;
performing a first dry etching process to form an insulating layer, a polysilicon layer, and a mask layer; and
performing a second dry etching process using the mask layer as a mask to form a notch region on the insulating layer and a lower region of the polysilicon layer.

10. The method according to claim 9, further comprising:
forming spacers at sides of the polysilicon layer;
forming source/drain regions in the substrate; and
forming a silicide layer on the polysilicon layer and the source/drain regions.

11. The method according to claim 9, wherein the mask material comprises a silicon oxide material.

12. The method according to claim 9, wherein performing the first dry etching process comprises:
using a pressure ranging between 55 and 85 mTorr;
using a source power ranging between 550 and 900 W;
using a bias power ranging between 50 and 70 W; and
using HBr, He, and O₂.

13. The method according to claim 12, wherein using HBr, He, and O₂ comprises using a flow rate of HBr ranging between 320 and 480 sccm, and a flow rate of He/O₂ ranging between 12 and 18 sccm.

14. The method according to claim 9, wherein performing the second dry etching process comprises:
using a pressure ranging between 10 and 14 mTorr;
using a source power ranging between 140 and 210 W;
using a bias power ranging between 50 and 60 W; and
using HBr and O₂.

15. The method according to claim 14, wherein using HBr and O₂ comprises using a flow rate of HBr ranging between 120 and 180 sccm and a flow rate of 02 ranging between 3 and 5 sccm.

16. The method according to claim 9, wherein the notch region slants towards an inner region of the polysilicon layer.

17. The method according to claim 9, wherein a channel length of the insulating layer is reduced by the notch region.

18. The method according to claim 9, wherein by the insulating layer and the polysilicon layer provide a gate structure of a transistor.

19. The method according to claim 18, wherein a critical dimension of the gate structure is reduced by the notch region.

20. The method according to claim 18, wherein a channel length of the transistor is reduced by the notch region.
